(19) United States
(12) Patent Application Publication
(10) Pub. No.: US 2025/0031472 A1
(43) Pub. Date: Jan. 23, 2025

(54) DEEP TRENCH ISOLATION STRUCTURE AND METHODS FOR FABRICATION THEREOF

(71) Applicant: TAIWAN SEMICONDUCTOR MANUFACTURING COMPANY, LTD., Hsinchu (TW)

(72) Inventors: Sheng Chieh CHUANG, Hsinchu (TW); Shu Yen KUNG, Tainan City (TW); Tsun-Kai TSAO, Tainan City (TW); Ming Chyi LIU, Hsinchu (TW)

(21) Appl. No.: 18/224,994

(22) Filed: Jul. 21, 2023

(51) Int. Cl. H01L 27/146

(52) U.S. Cl. CPC H01L 27/1463; H01L 27/14683; H01L 27/14634

(57) ABSTRACT

Embodiments of the present disclosure relate to a structure, which includes a plurality of photodiode doping regions formed in a substrate, and a deep trench isolation (DTI) structure formed in the substrate, wherein the DTI structure separates photodiode doping regions, and the DTI structure comprises a first filling material defining an air gap therein. The first filling material includes a top, a sidewall, and a bottom. The structure also includes a first isolation layer surrounding and in contact with the top, the sidewall, and the bottom of the first filling material.

### BACKGROUND

Integrated circuits (ICs) with image sensors are used in a wide range of modern day electronic devices. In recent years, complementary metal-oxide semiconductor (CMOS) image sensors have begun to see widespread use due to low power consumption, its small size, fast data processing, and low manufacturing cost. Deep trench isolation (DTI) structures are used to provide electrical and/or optical isolations between high voltage devices and image sensors. As the image pixel sizes and the spacing between neighboring image pixels continues to shrink, it is challenging to gap fill material layers in the DTI structures without defects.

### BRIEF DESCRIPTION OF THE DRAWINGS

Aspects of the present disclosure are best understood from the following detailed description when read with the accompanying figures. It is noted that, according to the standard practice in the industry, various features are not drawn to scale. In fact, the dimensions of the various features may be arbitrarily increased or reduced for clarity of discussion.

FIG. 1 is a flow chart of a method for fabricating a semiconductor device including DTI structures according to embodiments of the present disclosure.

FIGS. 2-14 schematically illustrate a semiconductor device at various stages of fabrication according to the method of FIG. 1.

FIG. 8A illustrates an enlarged view of a portion of the semiconductor device of FIG. 8, in accordance with some embodiments.

FIG. 10A illustrates an enlarged view of a portion of the semiconductor device of FIG. 10, in accordance with some embodiments.

FIG. 11A illustrates an enlarged view of a portion of the semiconductor device of FIG. 11, in accordance with some embodiments.

FIG. 12A illustrates an enlarged view of a portion of the semiconductor device of FIG. 12, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A Deep Trench Isolation (DTI) structure in a semiconductor substrate and the method of forming the same are provided according to various embodiments. The intermediate stages of forming the DTI structure are illustrated according to some embodiments. The DTI structure may be used for Backside Illumination (BSI) Complementary Metal-Oxide-Semiconductor (CMOS) image sensors, Front Side Illumination (FSI) CMOS image sensors, logic devices, and any suitable devices in which deep trench isolation are used. In image sensing devices, DTI structures may be formed on a front side of the semiconductor substrate with the transistors of the pixel elements or on the backside of the semiconductor substrate. Backside DTI structures that are fabricated after metallization process. Various embodiments of the present disclosure are suitable for gap filling high aspect-ratio (e.g., 1:3 to 1:10) backside DTI structures with narrower top critical dimension (CD) and bow profile. Details of variations of embodiments will be discussed below.

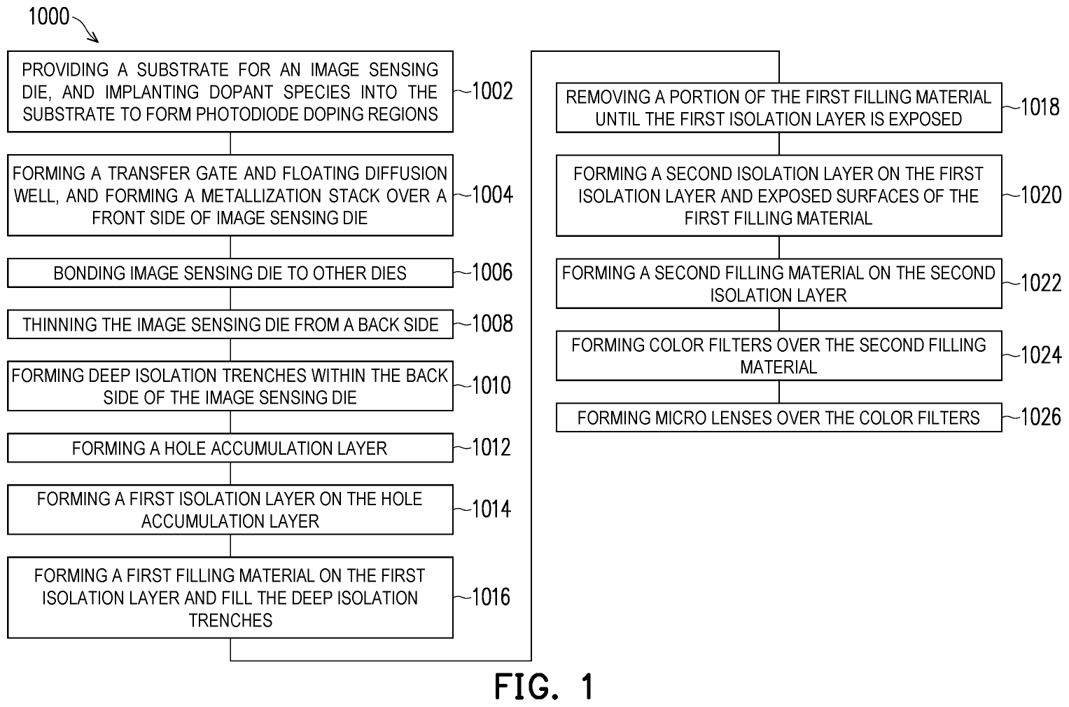

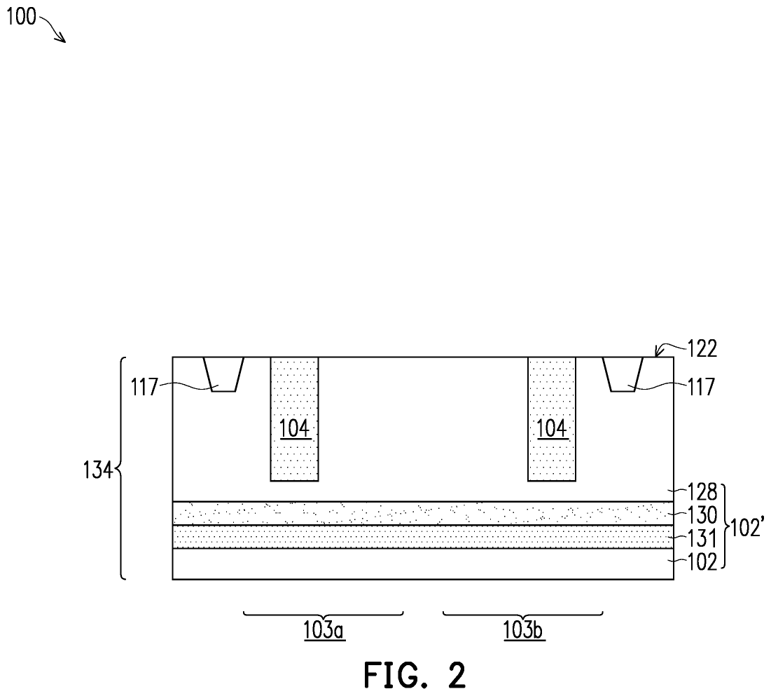

FIG. 1 is a flowchart of a method 1000 for fabricating a semiconductor device 100 including BDTI structures according to embodiments of the present disclosure. FIGS. 2-15 schematically illustrate the semiconductor device 100 at various stages of fabrication according to the method 1000. It is understood that additional steps can be provided before, during, and/or after the method 1000, and some of the steps described can be replaced, eliminated, and/or moved around for additional embodiments of the method 1000.

At operation 1002 of the method 1000, a substrate 102′ is provided for an image sensing die 134, as shown in FIG. 2. The substrate 102′ may include an elementary semiconductor such as germanium; a compound semiconductor including silicon carbon, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates such as multi-layered or gradient substrates may also be used. The substrate 102′ may include any type of semiconductor body, such as a semiconductor wafer or one or more die on a wafer, as well as any other type of semiconductor and/or epitaxial layers formed thereon and/or otherwise associated therewith. For example, a pixel array deep p-type well 131 may be formed on a handling substrate 102. The handling substrate 102 can be or be comprised of a highly doped p-type substrate layer. A pixel array deep n-type well 130 may be formed on the pixel array deep p-type well 131. The pixel array deep n-type well 130 and the pixel array deep p-type well 131 may be formed by implantation processes. In some embodiments, a photodiode doping layer 128 is formed as an upper portion of the substrate 102′. The photodiode doping layer 128 may be formed by a p-type epitaxial process. In some embodiments, a plurality of shallow trench isolation (STI) structures 117 is formed at a boundary and/or between adjacent pixel regions 103a, 103b from a front side 122 of the image sensing die 134 to a position within the photodiode doping layer 128. The one or more STI structures 117 may be formed by selectively etching the front side 122 of the image sensing die 134 to form shallow trenches and subsequently forming an oxide within the shallow trenches.

After the STI structures 117 are formed, dopant species are implanted into the photodiode doping layer 128 to form a plurality of photodiode doping regions 104. While not shown, each photodiode doping region 104 corresponds to one pixel element and functions as the light sensing area in the pixel element. The photodiode doping regions 104 may be formed by implanting n-type dopant species respectively within the pixel regions 103a, 103b. The photodiode doping layer 128 may be selectively implanted according to patterned masking layers (not shown), which may be any suitable photoresist. In some embodiments, the plurality of photodiode doping regions 104 may include n-type dopants at a concentration in a range between about 1E15 atom/cm³ and about 1E20 atom/cm³.

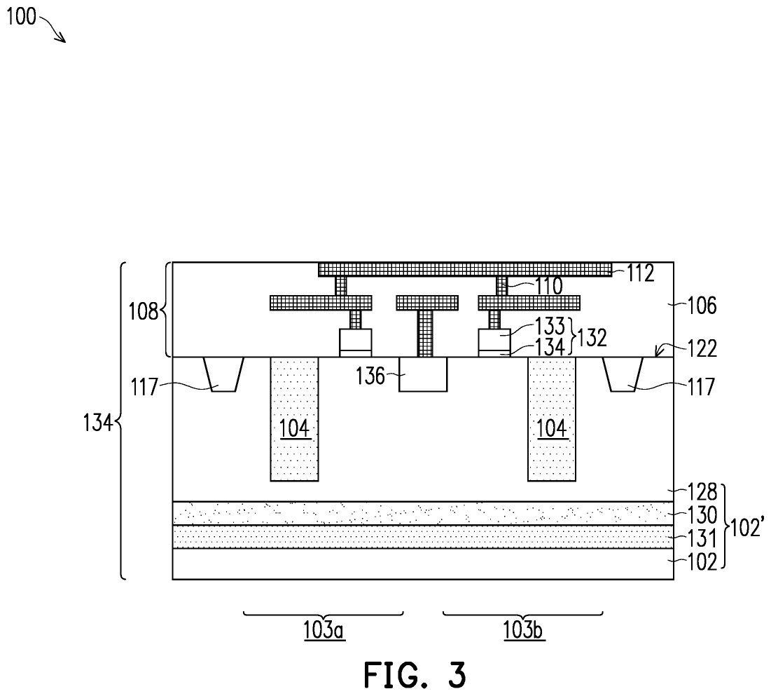

At operation 1004 of the method 1000, a transfer gate 132 is formed over a front side 122 of the image sensing die 134, as shown in FIG. 3. The transfer gate 132 may be formed by depositing a gate dielectric layer and a gate electrode layer over the substrate 102′. The gate dielectric layer and the gate electrode layer are then subsequently patterned to form a gate dielectric layer 133 and a gate electrode layer 134. In some embodiments, an implantation process is performed within the front side 122 of the image sensing die 134 to form a floating diffusion well 136 along one side of the transfer gate 132 or opposing sides of a pair of the transfer gates 132.

Thereafter, a metallization stack 108 is formed on the front side 122 of the image sensing die 134. The metallization stack 108 may be formed by forming an ILD layer 106, which includes one or more layers of ILD material, on the front side 122 of the image sensing die 134. The ILD 106 is subsequently etched to form via holes and/or trenches. The via holes and/or trenches are then filled with a conductive material to form the plurality of metal interconnect vias 110 and metal lines 112. The ILD 106 may include a low-k material, such as SiOₓ, SiOₓC_{y}H_{z}, SiOCN, SiON, or SiOₓC_{y}, where x, y and z are integers or non-integers, and may be deposited by any suitable deposition technique such as CVD, PECVD, PVD, etc. The plurality of metal interconnect layers may be formed using a deposition process and/or a plating process, such as electroplating, electro-less plating, etc. The plurality of metal interconnect layers may include tungsten, copper, aluminum copper, for example.

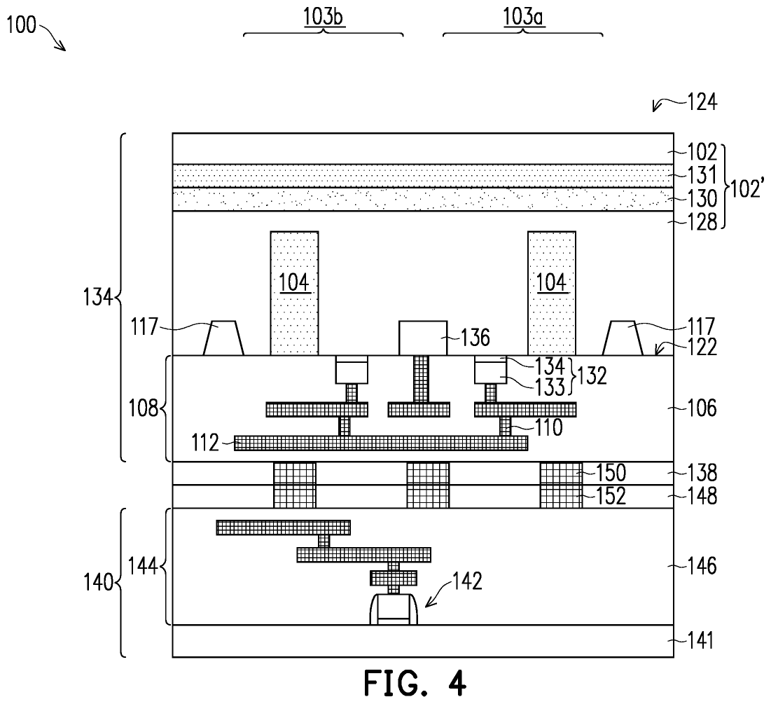

At operation 1006 of the method 1000, the image sensing die 134 may then be bonded to one or more other dies, as shown in FIG. 4. For example, the image sensing die 134 can be bonded to a logic die 140, which may include logic devices 142 disposed over a logic substrate 141. The logic die 140 may further include a metallization stack 144 disposed within an ILD layer 146 overlying the logic devices 142. The image sensing die 134 and the logic die 140 may be bonded face to face, face to back, or back to back. As an example, FIG. 4 shows a bonding structure where a pair of intermediate bonding dielectric layers 138, 148 (dielectric-to-dielectric bonding), and bonding pads 150, 152 (metal-to-metal bonding) are arranged between the image sensing die 134 and the logic die 140 and respectively bond the metallization stacks 108, 144 through a fusion or a eutectic bonding structure. An annealing process may follow the hybrid bonding process, and may be performed at a temperature range between about 250 degrees Celsius to about 450 degrees Celsius for about 0.5 hours to about 4 hours, for example.

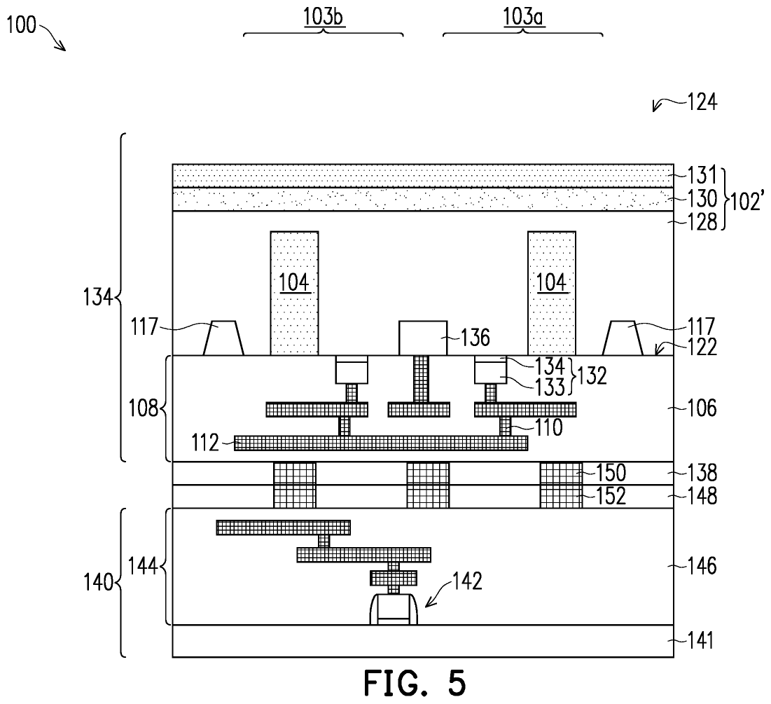

At operation 1008 of the method 1000, a thinning process is performed on a back side 124 (opposite to the front side 122) of the image sensing die 134, as shown in FIG. 5. The thinning process may partially or completely remove the handling substrate 102 (FIG. 4). The thinning or removal of the handling substrate 102 allows for radiation to pass through the back side 124 of the image sensing die 134 to the photodiode doping regions 104. In some embodiments, the image sensing die 134 is further thinned to expose a portion of the photodiode doping regions 104, such that radiation can reach on the photodiode more easily. The substrate 102′ may be thinned by etching the back side of the image sensing die 134. Alternatively, the substrate 102′ may be thinned by mechanical grinding the back side 124 of the image sensing die 134. In some embodiments, the substrate 102′ may be firstly grinded to a first thickness, then a wet etch process may be applied to further reduce the thickness of the substrate 102′ from the first thickness to a second thickness. After the thinning process, the radiation can easily pass through the back side 124 of the image sensing die 134 to reach the photodiode doping regions 104.

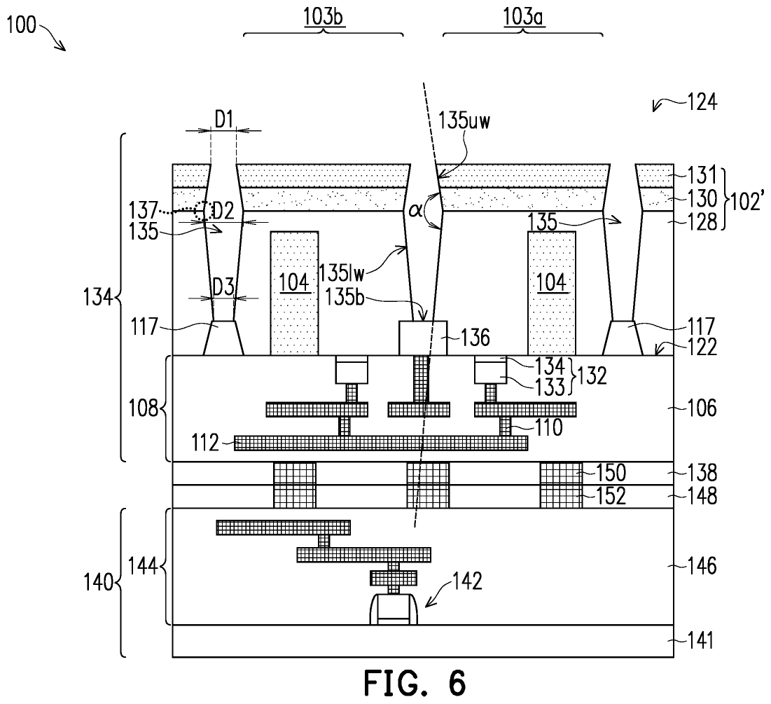

At operation 1010 of the method 1000, the substrate 102′ is selectively etched to form deep isolation trenches 135 within the back side 124 of the image sensing die 134, as shown in FIG. 6. The deep isolation trenches 135 laterally separate the photodiode doping regions 104. When viewed from the top, the deep isolation trenches 135 form a grid and surround the plurality of photodiode doping regions 104. In some embodiments, the substrate 102′ may be etched by forming a masking layer onto the back side of the image sensing die 134, followed by an anisotropic etching process. The substrate 102′ is then exposed to an etchant in regions not covered by the masking layer. The etchant removes a portion of the substrate 102′ to form the deep isolation trenches 135 extending into the substrate 102′, such as into the photodiode doping layer 128. In some alternative embodiments, some of the deep isolation trenches 135 may extend through the thickness of the substrate 102′ to provide full coverage to the photodiode doping regions 104. The masking layer may include photoresist or a nitride (e.g., SiN) patterned using a photolithography process. In various embodiments, the etchant may include a dry etchant having an etching chemistry comprising a fluorine species (e.g., CF₄, CHF₃, C₄F₈, etc.) or a wet etchant (e.g., hydroflouric acid (HF) or tetramethylammonium hydroxide (TMAH)). In cases a dry etching process is used, the plasma may be formed by Inductively Coupled Plasma (ICP), Transformer Coupled Plasma (TCP), Electron Cyclotron Resonance (ECR), Reactive Ion Etch (RIE), or the like. Each deep isolation trench 135 may have a depth range between about 1.5 μm and about 5 μm (measuring from the back side 124 of the image sensing die 134), and a lateral dimension in a range of about 0.1 μm to about 1 μm. If the depth of the deep isolation trenches 135 is less than about 1.5 μm, the deep isolation trenches 135 may not isolate the photodiode doping regions 104 properly. On the other hand, if the depth of the deep isolation trenches 135 is greater than about 5 μm, the deep isolation trenches 135 may damage STI structures 117 and/or the floating diffusion well 136.

The profile of the deep isolation trenches 135 may be achieved by varying the bias power applied to the semiconductor device 100, the thickness/type of the masking layer, gas type, the chamber pressure, etc. In various embodiments, the anisotropic etching process is performed such that the deep isolation trenches 135 have a first dimension D1 at or near the opening of the deep isolation trenches 135, a second dimension D2 at a turning point 137 that is away from the opening, and a third dimension D3 at the bottom of the deep isolation trenches 135. In some embodiments, the second dimension D2 is greater than the first dimension D1, and the first dimension D1 is greater than the third dimension D3. In some embodiments, the first dimension D1 is greater than the second dimension D2, and the second dimension D2 is greater than the third dimension D3. The resulting deep isolation trenches 135 may have a narrower top critical dimension (CD) and bowing tip (or under-cut) profile at the upper portion of the deep isolation trenches 135, and a tapering profile at the lower portion of the deep isolation trenches 135.

In one exemplary embodiment shown in FIG. 6, an upper portion of the sidewalls 135uw (e.g., the portion above the turning point 137) is gradually increased in diameter along a direction away from the back side 124, and a lower portion of the sidewalls 1351w (e.g., the portion below the turning point 137) is gradually reduced in diameter along the direction away from the back side 124. An angle “a” between the sidewall 135uw and the sidewall 1351w may be greater than about 140 degrees, such as about 160 degrees to about 175 degrees. In some embodiments, the anisotropic etching process is performed so that the sidewalls 135uw, 1351w of the deep isolation trenches 135 are straight and vertical, i.e., the sidewalls 135uw, 1351w are substantially perpendicular to the back side 124 (i.e., no turning point). In some embodiments, the deep isolation trenches 135 may also be slightly tapered, and hence the sidewalls 135uw, 1351w of the deep isolation trenches 135 are slightly tilted relative to the back side 124.

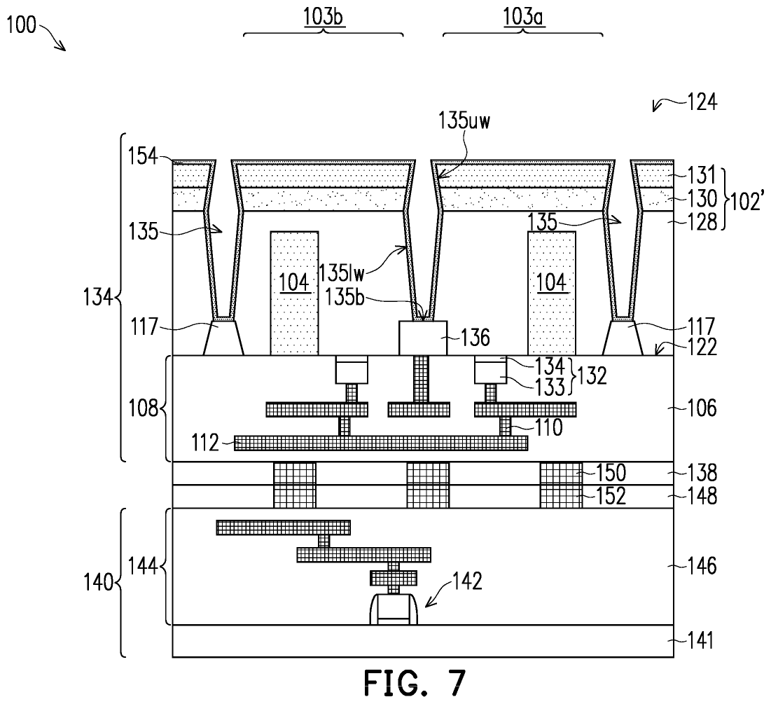

At operation 1012 of the method 1000, a hole accumulation layer 154 is formed on the exposed surfaces of the semiconductor device 100, as shown in FIG. 7. In one embodiment, the hole accumulation layer 154 is deposited on the sidewalls 135uw, 1351w and the bottom 135b of the deep isolation trenches 135. The hole accumulation layer 154 has a relatively high band-gap material (e.g., about 5.5 eV or greater). The hole accumulation layer 154 may include, but are not limited to, aluminum oxide (Al₂O₃), hafnium oxide (HfO₂), magnesium oxide (MgO), calcium oxide (CaO), zirconium oxide (ZrO₂), yttrium oxide (Y₂O₃), zirconium silicon oxide (ZrSiO₄), hafnium silicon oxide (HfSiO₄), combinations thereof, or the like, and may be deposited using a conformal deposition method such as atomic layer deposition (ALD), plasma enhanced atomic layer deposition (PEALD), chemical vapor deposition (CVD), or the like. In some embodiments, the hole accumulation layer 154 may have a thickness in a range between about 50 angstroms and about 200 angstroms. In some embodiments, the hole accumulation layer 154 is a multi-layered structure using two or more layers of material discussed herein. In such a case, an adhesion layer, such as an oxide layer, may be formed between the layers.

The use of a relatively high band-gap material allows the hole accumulation layer 154 to induce hole accumulation within the deep isolation trenches 135, thereby providing improved electrical isolation between the photodiode doping regions 104. The hole accumulation layer 154 may also act as a passivation layer to reduce while pixel degradation, which may have occurred as a result of damage to the substrate 102′ from etching deep isolation trenches 135. In some embodiments, the hole accumulation layer 154 is formed of a high-K material which may have advantageously optical reflective properties to provide optical isolation between the photodiode doping regions 104.

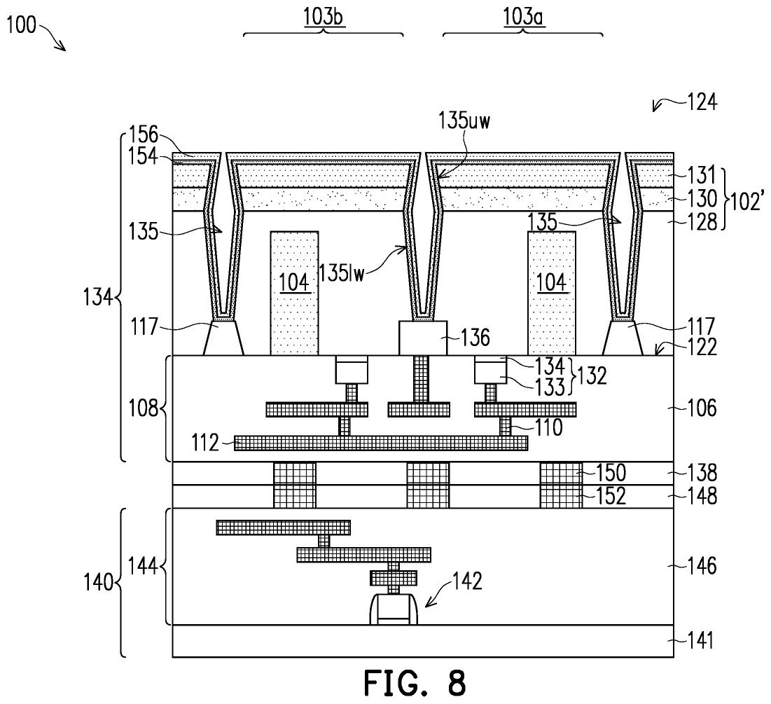

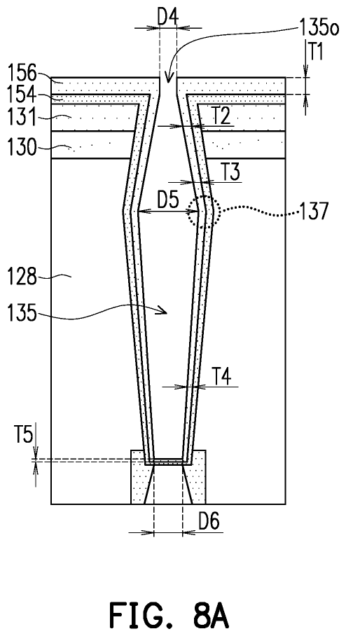

At operation 1014 of the method 1000, a first isolation layer 156 is deposited on the hole accumulation layer 154, as shown in FIG. 8. The first isolation layer 156 is configured to enhance electrical isolation between the photodiode doping regions 104. The material of the first isolation layer 156 is chosen to increase absorption of radiation from the photodiode doping regions 104, thereby preventing unwanted optical reflection back to the photodiode doping regions 104. Suitable materials for the first isolation layer 156 may include, but are not limited to, tantalum oxide (Ta₂O₅), titanium oxide (TiO₂), lutetium oxide (Lu₂O₃), lanthanum oxide (La₂O₃), hafnium aluminum oxide (HfAlO), any suitable high-K material, or the like, or a composite layer including more than one of these layers. Alternatively, the first isolation layer 156 may use the material for the hole accumulation layer 154. In such cases, the first isolation layer 156 and the hole accumulation layer 154 may use a material chemically different from one another. The first isolation layer 156 may be deposited using any suitable deposition technique, such as physical vapor deposition (PVD), ALD, or the like. In one embodiment, the first isolation layer 156 is Ta₂O₅ deposited by PVD.

The first isolation layer 156 is a continuous layer having a thickness changing in a range of about 1 μm to about 120 μm. In various embodiments, the first isolation layer 156 is deposited so that the first isolation layer 156 outside the deep isolation trenches 135 has a first thickness T1, and the first isolation layer 156 inside the deep isolation trenches 135 has a thickness gradually decreased along the direction away from the opening 135o of the deep isolation trenches 135, as shown in FIG. 8A. That is, the first isolation layer 156 inside the deep isolation trenches 135 and near the opening 135o has a second thickness T2, a third thickness T3 at or near the turning point 137 that is less than the second thickness T2, a fourth thickness T4 near the bottom of the deep isolation trenches 135 that is less than the third thickness T3, and a fifth thickness T5 at the bottom of the deep isolation trenches 135 that is less than the fourth thickness T4. After deposition of the first isolation layer 156, the deep isolation trenches 135 has a dimension D4 at the opening 135o, a dimension D5 at and/or near the turning point 137, and a dimension D6 at the bottom of the deep isolation trenches 135, wherein the dimension D5 is greater than the dimension D4, and the dimension D4 is greater than the dimension D6.

In some embodiments, the first thickness T1 may be substantially the same as the second thickness T2. In some embodiments, the first thickness T1 may be slightly less than the second thickness T2.

If the thickness of the first isolation layer 156 is less than about 1 μm, the first isolation layer 156 may not provide adequate ability of electrical isolation between the photodiode doping regions 104. A thickness greater than about 120 μm may prematurely pinch off the opening 135o and not provide additional benefit. In some embodiments, a ratio of the thickness of the first isolation layer 156 over the thickness of the hole accumulation layer 154 is in a range between 0.01 and 1.0.

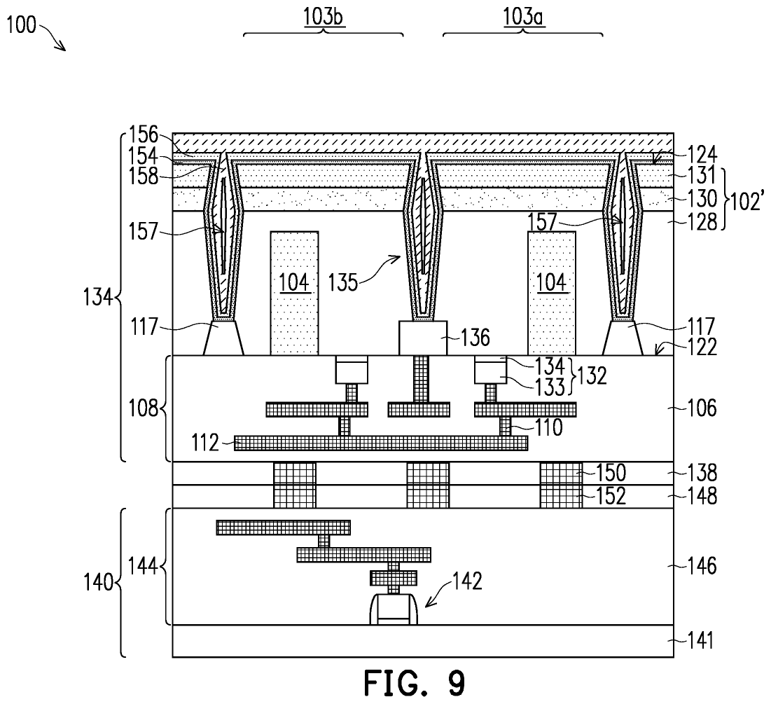

At operation 1016 of the method 1000, a first filling material 158 is deposited on the first isolation layer 156 and fill the deep isolation trenches 135 (FIG. 8), as shown in FIG. 9. Due to the profile of the deep isolation trenches 135, an air gap or seam 157 is formed within the first filling material 158 in the deep isolation trenches 135 after deposition of the first filling material 158. The air gap or seam 157 may be about 65% to about 90% of the height of the deep isolation trench 135. The top of the air gap or seam 157 is at an elevation below the back side 124 of the substrate 102′. In some embodiments, the first filling material 158 may be a dielectric material. For example, the first filling material 158 may be an oxide, such as silicon oxide. The first filling material 158 may be deposited using any suitable process, such as CVD or ALD. In some embodiments, the silicon oxide is formed by CVD using a suitable precursor, such as silane (SiH₄) or tetraethoxysilane or Si(OCH₅)₄ (TEOS). The first filling material 158 may over fill the deep isolation trenches 135 after deposition. The first filling material 158 may be deposited to a thickness of about 2000 angstroms or above, such as about 2500 angstroms to about 4000 angstroms.

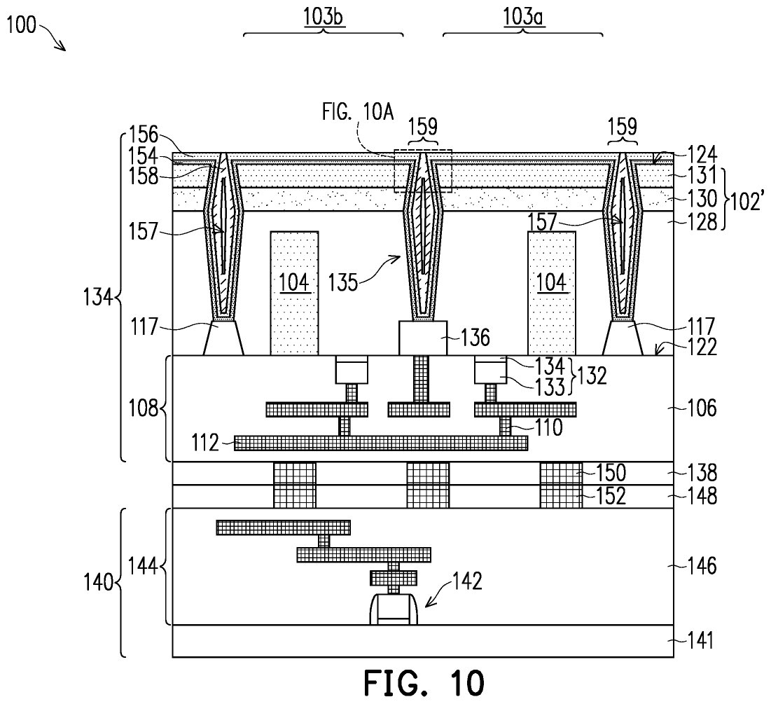

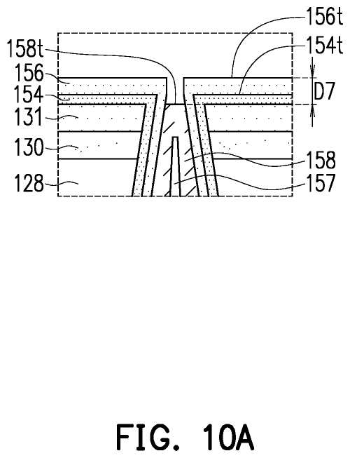

At operation 1018 of the method 1000, an etch process, such as a wet etch, a dry etch, or a combination thereof, is performed on the semiconductor device 100 until a portion of the first isolation layer 156 is exposed, as shown in FIG. 10. The first isolation layer 156 serves as an etch stop layer to prevent damage to the hole accumulation layer 154 and the substrate 102′. The first filing material 158 forms the majority of a backside deep trench isolation (BDTI) structure 159. In some cases, the first filling material 158, the first isolation layer 156, and the hole accumulation layer 154 in the deep isolation trenches 135 together are considered as a BDTI structure 159. The BDTI structure 159 forms a BDTI grid surrounding the plurality of photodiode doping regions 104. Each photodiode doping region 104 corresponds to one pixel element and functions as the light sensing area in the pixel element. The BDTI structure 159 provides optical and electrical isolation to the plurality of photodiode doping regions 104, and therefore, separates individual pixel elements.

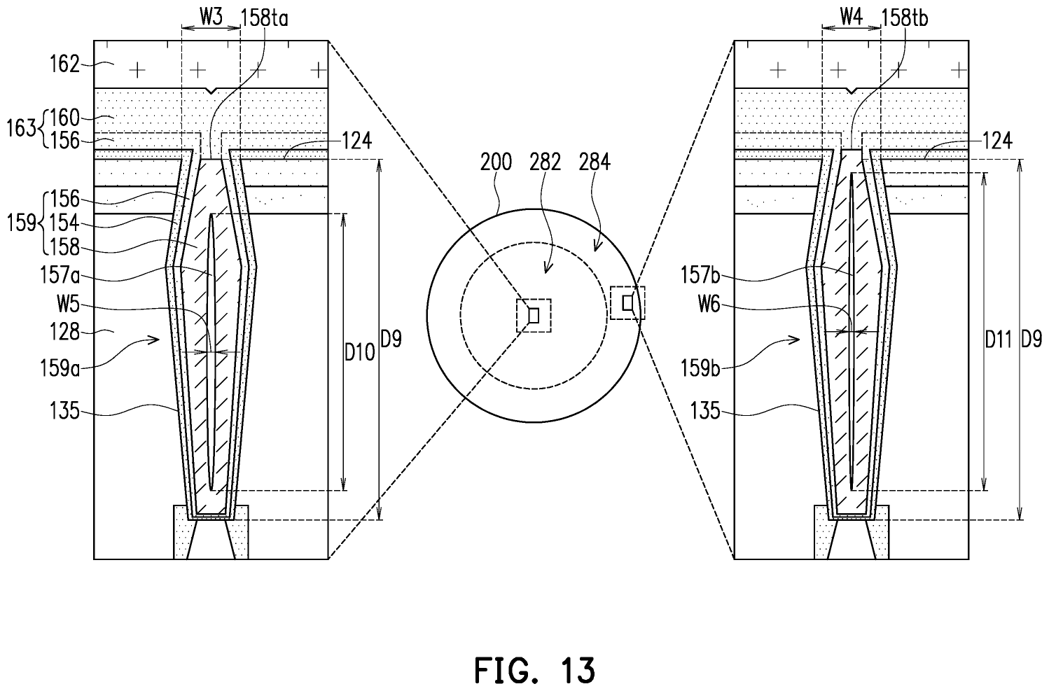

In some embodiments, a portion of the first filling material 158 at or near the opening 135o may be recessed after the etch process, as shown in FIG. 10A. In such cases, the top 158t of the first filling material 158 may be at an elevation below the top 156t of the first isolation layer 156 by a distance D7. The top 158t of the first filing material 158 may be at the same elevation as the back side 124 of the substrate 102′. In some embodiments, the top 158t of the first filling material 158 and the top 154t of the hole accumulation layer 154 are at substantially the same elevation. In some embodiments, the top 158t of the first filling material 158 and the top 156t of the first isolation layer 156 are at substantially the same elevation. As will be discussed in more detail below with respect to FIG. 13, the top of the first filling material 158 at a center region of a wafer may be at a first elevation and the top of the first filling material 158 at an edge region of the wafer may be at a second elevation that is higher than the first elevation.

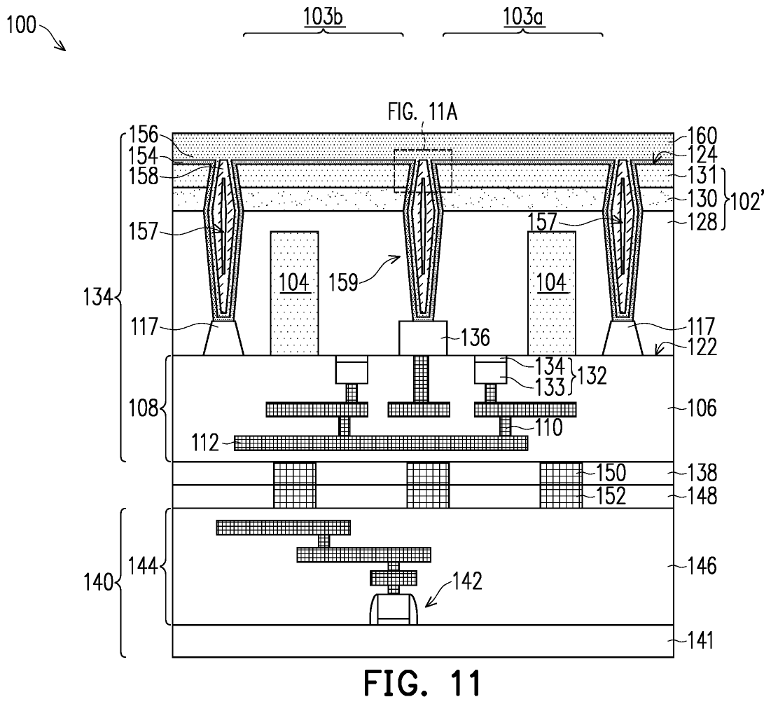

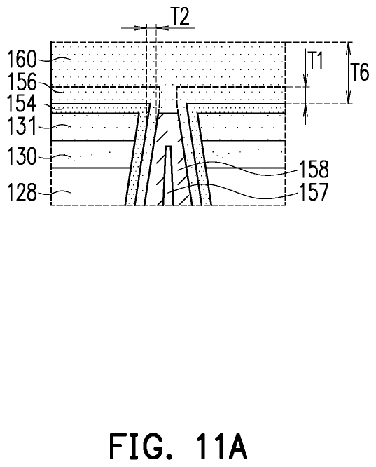

At operation 1020 of the method 1000, a second isolation layer 160 is deposited on the first isolation layer 156 and exposed surfaces of the first filling material 158, as shown in FIG. 11. The second isolation layer 160 may include the same material as the first isolation layer 156, and may be deposited using the same deposition technique as discussed above with respect to FIG. 8. In some embodiments, the second isolation layer 160 and the first isolation layer 156 include a material that is chemically different from one another. The second isolation layer 160 may be deposited so that the combined thickness T6 of the first and second isolation layers 156, 160 is greater than the thickness T2 of the first isolation layer 156 inside the deep isolation trenches 135 (FIG. 8A) and/or near the opening 135o (FIG. 8A). In some embodiments, the combined thickness T6 is at least twice the thickness T1 of the first isolation layer 156. For example, the second isolation layer 160 may have a thickness of about 350 angstroms to about 500 angstroms. FIG. 11A illustrates an enlarged view of a portion of the semiconductor device 100 in accordance with some embodiments. In various embodiments, the thickness T2 and the combined thickness T6 is at a ratio (T2:T6) of about 1:3 to about 1:5. While not shown, it is understood that the thickness of the first isolation layer 156 in the deep isolation trenches 135 is gradually changing along the direction away from the opening 135o of the deep isolation trenches 135, as discussed above in FIG. 8A.

In some embodiments, the combined thickness T6 of the first and second isolation layers 156, 160 is substantially identical to the thickness T2 of the first isolation layer 156 inside the deep isolation trenches 135 (FIG. 8A) and/or near the opening 135o (FIG. 8A).

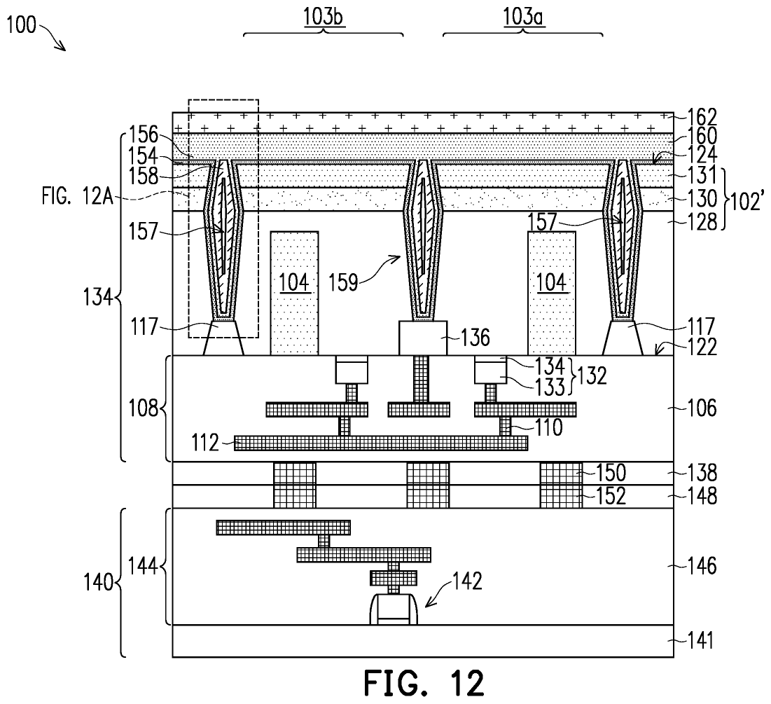

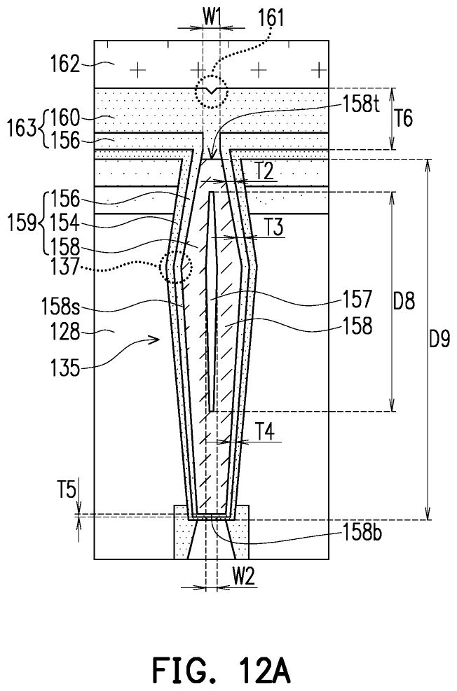

At operation 1022 of the method 1000, a second filling material 162 is deposited on the second isolation layer 160, as shown in FIG. 12. The second filling material 162 is configured to increase absorption of radiation by the photodiode doping regions 104 by providing for a low reflection of radiation from the substrate 102′. The second filling material 162 may be deposited to have a first thickness of about 1500 angstroms to about 3000 angstroms. After the deposition of the second filling material 162, a planarization process, such as a CMP process, is performed so that the thickness of the second filling material 162 is reduced from the first thickness to a second thickness. The second filling material 162 may include the same material as the first filling material 158, and may be deposited using the same deposition technique as the first filling material 158. In some embodiments, the second filling material 162 may comprise a high-K dielectric material and a layer of silicon oxide. The use of two-step deposition of isolation materials (i.e., first and second isolation layers 156, 160) is advantageous for gap-filling high aspect ratio deep isolation trenches 135 despite the small critical dimension of the deep isolation trenches 135. This is because the thinner layer of first isolation layer 156 allows deposition of the first isolation layer 156 in the deep isolation trenches 135 without prematurely pinching off the opening 135o of the deep isolation trenches 135, while the thicker layer of second isolation layer 160, which is deposited after the first filling material 158 is formed in the deep isolation trenches 135, ensures the isolation material is formed with desired thickness and defects free. When gap filling ability is improved, smaller air gap or seam is formed and therefore less defects generated after thermal or CMP process.

FIG. 12A illustrates an enlarged view of a portion of the semiconductor device 100 in accordance with some embodiments. The sidewall 158s, the bottom 158b, and the top 158t of the first filling material 158 of the BDTI structure 159 is surrounded and in contact with the first isolation layer 156. In one embodiment, a portion of the second isolation layer 160 may have a recess 161 above the BDTI structure 159. The recess 161 may be formed due to the height difference (i.e., distance D7 shown in FIG. 10A) between the top 158t of the first filling material 158 and the top 156t of the first isolation layer 156. The air gap or seam 157 may have a height D8 that is about 55% to about 90% (e.g., about 75%-85%) of the height D9 of the deep isolation trench 135. In some embodiments, the top 158t of the first filling material 158 in the deep isolation trenches 135, which is an interface defined by the second isolation layer 160 and the first filling material 158, has a width W1. The interface is disposed at an elevation above the air gap or seam 157 and radially across the entire width of the air gap or seam 157. The first isolation layer 156 and the second isolation layer 160 (collectively referred to as isolation cap 163) above the BDTI structure 159 extends over and across the first filling material 158 and the air gap or seam 157. Particularly, the isolation cap 163 has a thickness T8 that is greater than the thickness (e.g., T2, T3, T4, and T5) of the first isolation layer 156 within the deep isolation trenches 135.

FIG. 13 illustrates a schematic view of a wafer 200 showing an exemplary arrangement of semiconductor devices, in accordance with some embodiments. The wafer 200 can be fabricated to form a plurality of semiconductor devices, such as the semiconductor devices 100. The wafer 200 may have a center region 282 and an edge region 284 surrounding the center region 282. The semiconductor devices formed in the center region 282 and the edge region 284 are substantially identical to the semiconductor device 100 of FIG. 12 except that (1) a top 158ta of a BDTI structure 159a at the center region 282 is at substantially the same elevation as the back side 124 of the substrate 102′, while a top 158tb of a BDTI structure 159b at the edge region 284 is at an elevation higher than the back side 124 of the substrate 102′; and (2) air gap or seam 157a of the BDTI structure 159a at the center region 282 is has a first height D10, while air gap or seam 157b of the BDTI structure 159b at the edge region 284 is has a second height D11 greater than the first height D10. In some embodiments, the first height D10 is about 55% to about 75% of the height D9 of the deep isolation trench 135, while the second height D11 is about 75% to about 90% of the height D9 of the deep isolation trench 135. The deep isolation trench 135 at the center region 282 might have a width W3 measuring at the opening (e.g., 135o as shown in FIG. 8A) of the deep isolation trench 135, and the deep isolation trench 135 at the edge region 284 might have a width W4 measuring at the opening of the deep isolation trench 135, wherein the width W3 is substantially identical to the width W4.

In some embodiments, the air gap or seam 157a at the center region 282 has a width W5 and the air gap or seam 157b at the edge region 284 has a width W6 that is less than the width W5. In either case, the air gap or seam 157a, 157b is enclosed within the first filling material 158. The top of the air gap or seam 157a, 157b does not extend over the back side 124 of the semiconductor device 200. In some alternative embodiments, the top 158ta, 158tb of the first filling material layer 158 in the deep isolation trench 135 may be at substantially the same height as the back side 124 of the substrate 102′.

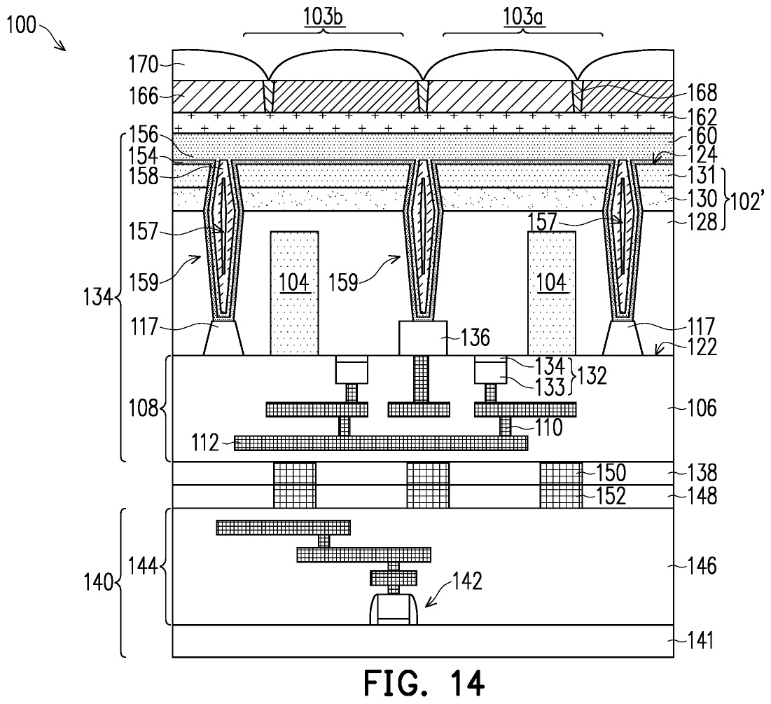

At operation 1024 of the method 1000, a plurality of color filters 166 are formed over the second filling material 162, as shown in FIG. 14. The color filters 166 are respectively configured to transmit specific wavelengths of incident radiation or incident light. For example, a first color filter (e.g., a red color filter) may transmit light having wavelengths within a first range, while a second color filter may transmit light having wavelengths within a second range different than the first range. In some embodiments, the plurality of color filters 166 are arranged within a grid structure overlying a plurality of the photodiode doping regions 104. In some embodiments, an isolation structure 168 may be formed between neighboring color filters 166 to prevent radiation transmitted from one or more color filters 166 from projecting into the photodiode doping regions 104 under neighboring color filters 166.

At operation 1026 of the method 1000, a plurality of micro lenses 170 are arranged over the plurality of color filters 166, as shown in FIG. 14. Respective micro lenses 170 are aligned laterally with the color filters 166 and substantially overlie the pixel regions 103a, 103b. The plurality of micro lenses 170 may have a flat bottom surface abutting the plurality of color filters 166 and a curved upper surface. The curved upper surface is configured to focus the incident radiation or incident light (e.g., light towards the underlying pixel regions 103a, 103b). The plurality of micro lenses 170 may be formed by depositing a micro lens material above the plurality of color filters 166 by a suitable process, such as a spin-on method or a deposition process. In some embodiments, a micro lens template having a curved upper surface is patterned above the micro lens material. The micro lens template may include a photoresist material, for example, for a negative photoresist. For a negative photoresist, more light is exposed at a bottom of the curvature and less light is exposed at a top of the curvature. The micro lens template is then developed and baked to form a rounding shape. The plurality of micro lenses 170 are then formed by selectively etching the micro lens material according to the micro lens template.

As shown in FIG. 14, the semiconductor device 100 is an imaging sensing device using the photodiode doping regions 104 as light sensing regions, and the photodiode doping regions 104 are separated from each other by the BDTI structure 159. The BDTI structure 159 functions as optical isolator preventing incident radiation or incident light from entering neighboring photodiode doping regions 104. Upon receiving the incident radiation or incident light, the photodiode doping regions 104 emit electrons due to the photoelectric effect. During operation of the image sensing die 134, the incident radiation or incident light is focused by the micro lenses 170 to the underlying pixel regions 103a, 103b. When incident radiation or incident light of sufficient energy strikes the photodiode doping regions 104, it generates an electron-hole pair that produces a photocurrent or charge. The transfer gate 132 controls charge transfer from the photodiode doping regions 104 to the floating diffusion well 136. If the charge level is sufficiently high within the floating diffusion well 136, a source follower transistor (not shown) is activated and charges are selectively output according to operation of a row select transistor (not shown) used for addressing. A reset transistor (not shown) can be used to reset the photodiode doping regions 104 between exposure periods.

Various embodiments or examples described herein offer multiple advantages over the state-of-art technology. By using two-step deposition of isolation material (i.e., first and second isolation layers 156, 160), the gap-filling of the high aspect ratio deep isolation trenches 135 is improved even though the critical dimension of the deep isolation trenches 135 is small. A thinner layer of first isolation layer 156 allows deposition of the first isolation layer 156 in the deep isolation trenches 135 without prematurely pinching off the opening 135o of the deep isolation trenches 135, while a thicker layer of second isolation layer 160, which is deposited after the first filling material 158 is formed in the deep isolation trenches 135, ensures the isolation material is formed with desired thickness. When gap filling ability is improved, the air gap or seam is enclosed within the first filling material 158 in the BDTI structure and does not extend over the BDTI structure. Therefore, the air gap or seam does not induce defects after thermal or CMP process. The use of two-step deposition of isolation material also eliminates film stress induced defects that may otherwise occur at interface between the back surface of semiconductor substrate and the isolation material. As a result, the yield of the semiconductor devices is improved.

Some embodiments of the present disclosure provide a structure including a plurality of photodiode doping regions formed in a semiconductor substrate, and a deep trench isolation (DTI) structure formed in the semiconductor substrate, wherein the DTI structure separates individual pixel elements, and the DTI structure comprises a first filling material defining an air gap therein. The first filling material includes a top, a sidewall, and a bottom. The structure also includes a first isolation layer surrounding and in contact with the top, the sidewall, and the bottom of the first filling material.

Some embodiments of the present disclosure provide a structure. The structure includes a deep trench isolation (DTI) structure extending a depth into a semiconductor substrate, wherein the DTI structure separates individual pixel elements, and the DTI structure comprises a filling material defining an air gap therein, and a high-K dielectric layer enclosing a sidewall and a bottom of the filling material. The structure also includes an isolation structure, comprising a first isolation layer disposed between and in contact with the high-K dielectric layer and the sidewall and the bottom of the filling material, and a second isolation layer disposed on the first isolation layer, wherein a portion of the second isolation layer is extended from and in contact with a top of the filling material.

Some embodiments of the present disclosure provide a method for forming an image sensor. The method includes forming a plurality of photodiode doping regions in and on a front side of a semiconductor substrate, forming deep isolation trenches from a back side of the substrate, wherein the deep isolation trenches separate the plurality of photodiode doping regions. The method also includes depositing a hole accumulation layer on sidewalls of the deep isolation trenches, depositing a first isolation layer on the hole accumulation layer, wherein the first isolation layer has a first thickness. The method also includes depositing a first filling material on the first isolation layer in the deep isolation trenches, wherein the first filling material encloses an air gap therein. The method further includes depositing a second isolation layer on the first isolation layer and exposed surfaces of the first filling material, wherein the second isolation layer has a second thickness greater than the first thickness.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A structure, comprising:
a plurality of photodiode doping regions formed in a substrate; and
a deep trench isolation (DTI) structure formed in the substrate, wherein the DTI structure separates photodiode doping regions, and the DTI structure comprises:
a first filling material defining an air gap therein, the first filling material comprises a top, a sidewall, and a bottom; and
a first isolation layer surrounding and in contact with the top, the sidewall, and the bottom of the first filling material.

2. The structure of claim 1, further comprising:
a second isolation layer disposed above and in contact with the first isolation layer.

3. The structure of claim 2, wherein the first isolation layer and the second isolation layer comprise the same material.

4. The structure of claim 1, further comprising:
a second filling material disposed over the second isolation layer, wherein the second filling material comprises the same material as the first filling material.

5. The structure of claim 2, wherein the top of the first filling material and the second isolation layer define a first interface, and the first interface is disposed across an entire width of the air gap.

6. The structure of claim 5, wherein the first interface has a first width and the air gap has a second width less than the first width.

7. The structure of claim 5, further comprising:
a high-K dielectric layer disposed between and in contact with the first isolation layer and the substrate.

8. The structure of claim 7, wherein the high-K dielectric layer is extended to between and in contact with the second isolation layer and a back surface of the substrate.

9. The structure of claim 8, wherein the top of the first filling material is at substantially the same elevation as the back surface of the substrate.

10. The structure of claim 7, wherein the top of the first filling material is at the same elevation as a second interface defined by the high-K dielectric layer and the second isolation layer.

11. A structure, comprising:
a deep trench isolation (DTI) structure extending a depth into a substrate, wherein the DTI structure separates photodiode doping regions, and the DTI structure comprises:
a filling material defining an air gap therein; and
a high-K dielectric layer enclosing a sidewall and a bottom of the filling material; and
an isolation structure, comprising:
a first isolation layer disposed between and in contact with the high-K dielectric layer and the sidewall and the bottom of the filling material; and
a second isolation layer disposed on the first isolation layer, a portion of the second isolation layer being extended from and in contact with a top of the filling material.

12. The structure of claim 11, wherein the second isolation layer extends across an entire width of the filling material.

13. The structure of claim 11, wherein the first isolation layer and the second isolation layer are formed from the same material.

14. The structure of claim 11, wherein the first isolation layer has a first thickness, and the second isolation layer has a second thickness different from the first thickness.

15. The structure of claim 14, wherein the first thickness is reduced along a direction away from the top of the filling material.

16. The structure of claim 11, wherein the DTI structure has a first dimension, a second dimension greater than the first dimension, and a third dimension less than the first dimension.

17. The structure of claim 11, wherein the air gap has a first height, and the DTI structure has a second height greater than the first height.

18. A method for forming an image sensor, comprising:
forming a plurality of photodiode doping regions in and on a front side of a substrate;
forming deep isolation trenches from a back side of the substrate, wherein the deep isolation trenches separate the plurality of photodiode doping regions;
depositing a hole accumulation layer on sidewalls of the deep isolation trenches;
depositing a first isolation layer on the hole accumulation layer, wherein the first isolation layer has a first thickness;
depositing a first filling material on the first isolation layer in the deep isolation trenches, wherein the first filling material encloses an air gap therein; and
depositing a second isolation layer on the first isolation layer and exposed surfaces of the first filling material, wherein the second isolation layer has a second thickness greater than the first thickness.

19. The method of claim 18, further comprising:
after depositing the first filling material, removing a portion of the first filling material until the first isolation layer is exposed.

20. The method of claim 18, further comprising:
depositing a second filling material on the second isolation layer, wherein the first and second filling materials comprise the same material.
